(19) United States
(12) Patent Application Publication
(10) Pub. No.: US 2016/0150662 A1
(43) Pub. Date: May 26, 2016

(54) Electrical Circuit and Method for Producing an Electrical Circuit for Activating a Load

(71) Applicant: ZF FRIEDRICHSHAFEN AG, Friedrichshafen (DE)

(72) Inventor: Thomas Maier, Neunburg v. Wald (DE)

(73) Assignee: ZF Friedrichshafen AG, Friedrichshafen (DE)

(21) Appl. No.: 14/899,461

(22) PCT Filed: May 26, 2014
(86) PCT No.: PCT/EP2014/060776

§ 371 Date: Dec. 17, 2015

(30) Foreign Application Priority Data
Jun. 27, 2013 (DE) 10 2013 212 446.5

(51) Int. Cl. H05K 7/02; H05K 7/20; H05K 3/30; H02K 11/33

(52) U.S. Cl. CPC H05K 7/02; H02K 11/33; H05K 7/20436; H05K 3/303

(57) ABSTRACT

The current embodiments provide an electrical circuit for controlling an electric motor for a vehicle. The electrical circuit may have a circuit board with a first surface and a second surface opposite the first surface, an intermediate circuit capacitor arranged on the first surface, and a power semiconductor arranged on the second surface and electrically connected with the intermediate circuit capacitor for providing electrical energy to the electric motor. The intermediate circuit capacitor and the power semiconductor may be arranged opposite to each other with respect to the circuit board.

The present embodiments relate to an electrical circuit and a method for producing an electrical circuit for controlling a load, for example an electric motor of a vehicle.

When controlling electric motors in the automotive industry for higher performance, power semiconductors are used in various configurations, e.g. H-bridges for DC motors (direct-current motors) or B6-bridges for BLDC motors (brushless direct-current motors). In particular power MOSFETs are used in the low-voltage range as discrete power semiconductors. At higher voltages, especially for hybrid systems, also bipolar transistors with insulated gate electrode are used. Such power semiconductors require cooling in order not to overheat during operation.

Controlling a load, such as a motor control, requires as a buffer an intermediate circuit capacitor which must be optimally arranged for reasons of electromagnetic compatibility. The intermediate circuit capacitor may also have to be cooled due to the ripple current and the resulting power dissipation.

Against this background, the present embodiment provides an improved electrical circuit for controlling a load and an improved method for making an electrical circuit for controlling a load according to the main claims. Advantageous embodiments result from the dependent claims and the description below.

If a power semiconductor has a heat conduction surface on a side opposite its mounting surface, the heat developing during the operation of the power semiconductor can be dissipated by the heat conduction surface. In this way it is not necessary or only to a small extent to remove heat through a circuit substrate on which the power semiconductor is mounted.

An electrical circuit for controlling a load, in particular an electric motor for a vehicle, comprises a circuit substrate having a first surface and a second surface opposite the first surface, an intermediate circuit capacitor arranged on the first surface and a power semiconductor arranged on the second surface and electrically conductively connected to the intermediate circuit capacitor for supplying electric power to the load.

The intermediate circuit capacitor and the power semiconductor are arranged on the circuit substrate opposite to each other with respect to the circuit substrate. As a result, an improved EMC (electromagnetic compatibility) connection of the individual components is achieved. It is of course possible that also other electronic components are arranged on the circuit carrier opposite the power semiconductor

The power semiconductor is purposefully designed as a reverse power output stage, in particular as a reverse MOSFET or direct-FET. The Intermediate circuit capacitors are appropriately SMD electrolytic capacitors, in particular polymer-electrolyte capacitors.

The power semiconductor has at least a first electrical terminal and a second electrical terminal, wherein the first electrical terminal is electrically conductively connected to a heat conducting surface arranged on the side of the power semiconductor facing away from the second surface of circuit substrate.

Under an electrical circuit can be understood, for example, a printed circuit board, a device or an electric device, such as a controller. The electrical circuit may comprise interfaces, for example, to a power supply or the load. The load can be an electrical load, for example, an electric machine. The electrical energy can be provided to operate the load as a direct current or an alternate current. The power semiconductor may have a control port, through which, for the example, an amount of the energy to be provided for the load or its time profile can be controlled. The power semiconductor can be designed in the form of a so-called reverse component, for example, a reverse end stage. The power semiconductors can have electrical connections on an assembly side, for example, a solder balls or solder pads or have solder connections, whose solder pads are directed to the mounting surface. On a side opposite to the mounting side the power semiconductor or a housing of the power semiconductor can have the heat conducting surface. The heat conducting surface can be electrically connected to at least one of the electrical connections of the power semiconductor. In this way, the heat developing in the interior of the power semiconductor can be very well conducted to the outside. The power semiconductor may represent an interface between an indirect invertor and an output circuit. For example, the power semiconductor can be part of an output stage of the electrical circuit or constitute such an output stage. In the output circuit can be arranged the load. In the intermediate circuit can be buffered electrical energy using the intermediate circuit capacitor. Under a Intermediate circuit capacitor can be understood a single capacitor or an interconnection such as a parallel connection of several individual capacitors. Under a circuit substrate can be understood a circuit board having a plurality of electrical cables.

Such an approach allows an absolutely space-saving arrangement of electronic components, an EMC-optimal (EMC=Electromagnetic Compatibility) connection of the Intermediate circuit capacitor and an improved cooling of the power components, such as one or more power semiconductors.

The first electrical terminal and the second electrical connection of the power semiconductor can be arranged on a side of the power semiconductor facing the second surface of the circuit substrate.

Alternatively, the solder pads or bonding pads of the first electrical terminal and the second electrical terminal can be facing the second surface of the circuit substrate. The power semiconductor may be formed to conduct the electrical power to the load through the first electrical terminal. For example, the first electrical terminal can be an input for connecting the power semiconductor with the intermediate circuit capacitor or an output for connecting the power semiconductor with the load. Since the terminals are arranged on the side of the power semiconductor facing the circuit substrate, the length of the lines within the power semiconductor can be kept very short. In addition, the power semiconductor can be designed, for example, as an SMD component.

The electrical circuit may comprise a power semiconductor heat sink. The power semiconductor heat sink can be connected to the heat-conducting surface of the power semiconductor. For example, a surface of the power semiconductor heat sink can be connected directly or via an intermediate layer with the heat-conducting surface. Thus, the power semiconductor heat sink can be mounted on the power semiconductor, or vice versa. This allows a very compact design. In addition, the heat developing during operation of the power semiconductor can be conducted away via the power semiconductor heat sink of the circuit substrate. This allows for the arrangement of other possibly temperature-sensitive components in the vicinity of the power semiconductor on the circuit substrate.

Further, the electrical circuit can comprise an intermediate circuit capacitor heat sink. The intermediate circuit capacitor heat sink may be connected to one side of the intermediate circuit capacitor facing away from the first surface of the circuit substrate. For example, a surface of the intermediate circuit capacitor heat sink can be connected directly or via an intermediate layer to the intermediate circuit capacitor. Thus, the intermediate circuit capacitor heat sink can be mounted on the intermediate circuit capacitor, or vice versa. Heat from the intermediate circuit capacitor can be dissipated by the intermediate circuit capacitor heat sink. This can prolong the life of the intermediate circuit capacitor. Advantageously, the intermediate circuit capacitor heat sink can be arranged so that the heat dissipated from the intermediate circuit capacitor can be led away from the circuit substrate.

A thermally conductive material may be arranged between the heat conducting surface of the power semiconductor and the power semiconductor heat sink. Accordingly, the intermediate circuit capacitor heat sink and the side of the intermediate circuit capacitor facing away from the first surface of the circuit board substrate can be arranged can be arranged a thermally conductive material. The heat-conductive material can be, for example, a paste, a film or an oxide layer, which can increase the heat transfer between the heat sink and the component to be cooled. In addition, the thermally conductive material can serve as a mechanical support of the component to be cooled.

According to one embodiment, the electrical circuit comprises a housing. In this case, the circuit substrate is arranged within the housing. A first wall of the housing can form the intermediate circuit capacitor heat sink. A second housing wall situated opposite to the first housing wall can form the power semiconductor heat sink. The first and the second housing walls can be arranged parallel to each other. The housing walls can be made of metal. Since the housing is used as a heat sink, additional heat sinks can be dispensed with. As a result, weight and space can be saved. In addition, the position of the intermediate circuit capacitor and the power semiconductor can be stabilized within the housing due to the direct contact with the housing.

According to one embodiment, the power semiconductor can be implemented as a transistor. The first electrical terminal, the second electrical terminal and a third electrical terminal of the transistor can be electrically connected to the circuit substrate by the contact surfaces arranged on the second surface of the circuit substrate. For example, the contact surfaces can be solder pads. The transistor may be a power transistor. For example, the transistor can be a MOSFET (metal-oxide-semiconductor field-effect transistor) or power MOSFET. Such a MOSFET can have a drain, a source and a gate terminal as electrical terminals. For example, the drain or source terminals can be electrically connected to the heat conducting surface. This can also be a bipolar transistor, a power bipolar transistor having a collector terminal, an emitter terminal and a base terminal or an IGBT (Insulated-gate bipolar transistor) with a collector terminal, an emitter terminal and a gate terminal. In a bipolar transistor, for example, the collector terminal or the emitter terminal can be electrically connected with the heat conducting surface.

According to one embodiment, the intermediate circuit capacitor and the power semiconductor can be so arranged on the circuit substrate that a base surface of the intermediate circuit capacitor facing the first surface of the circuit substrate overlaps with a base area of the intermediate circuit capacitor facing the second surface of the circuit substrate. Thus, the intermediate circuit capacitor and the power semiconductors can be arranged directly opposite each other on the circuit substrate. As a result, an electric line for connecting the intermediate circuit capacitor to the power semiconductor can be designed very short, for example, as a through-connection through the circuit substrate.

The electrical circuit can comprise at least one further intermediate circuit capacitor arranged on the first surface. Additionally or alternatively, the electrical circuit can comprise at least one further intermediate circuit capacitor arranged on the second surface of the power semiconductor for providing additional electrical energy for the load. The further power semiconductor can be electrically conductively connected to the at least one further intermediate circuit capacitor. For example, the electrical circuit can have three power semiconductors, through which, for example, a load in the form of a three-phase motor can be supplied with three-phase current. A number of the intermediate circuit capacitors can correspond to a number of power semiconductors. Alternatively, the number of intermediate circuit capacitors can be distinguished from a number of power semiconductors. In this way, the electrical circuit can be adapted to the requirements of the load.

A method for making an electrical circuit for controlling a load, in particular an electric motor for a vehicle comprises the steps of:

Providing a circuit substrate having a first surface and a second surface opposite the first surface;

Arranging an intermediate circuit capacitor on the first surface of the circuit substrate;

Arranging a power semiconductor for supplying electric power to the load on the second surface of the circuit substrate, wherein the power semiconductor comprises at least a first electrical terminal and a second electrical terminal, wherein the first electrical terminal is electrically conductively connected to a heat conducting surface arranged on a side of the power semiconductor facing away from the second surface of the circuit substrate; and

Electrically conductive connection of the power semiconductor with the intermediate circuit capacitor.

The electrically conductive connection of the power semiconductor with the intermediate circuit capacitor can be done for example by the steps of placing the intermediate circuit capacitor and the power semiconductor on the circuit substrate or by a separate step, for example, a heating of the assembly of circuit boards, intermediate circuit capacitor and power semiconductors.

The present embodiments are illustrated by way of example with reference to the accompanying drawings. The figures show:

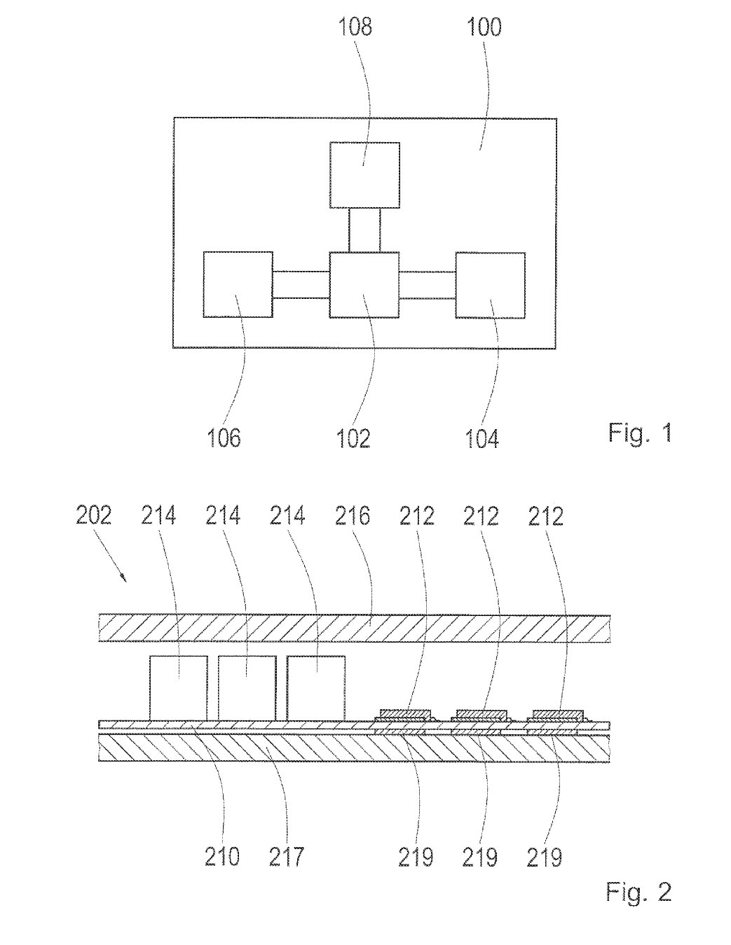

FIG. 1 shows a vehicle with an electrical circuit for controlling a load, according to an embodiment of the present embodiments;

FIG. 2 shows an electrical circuit for controlling a load;

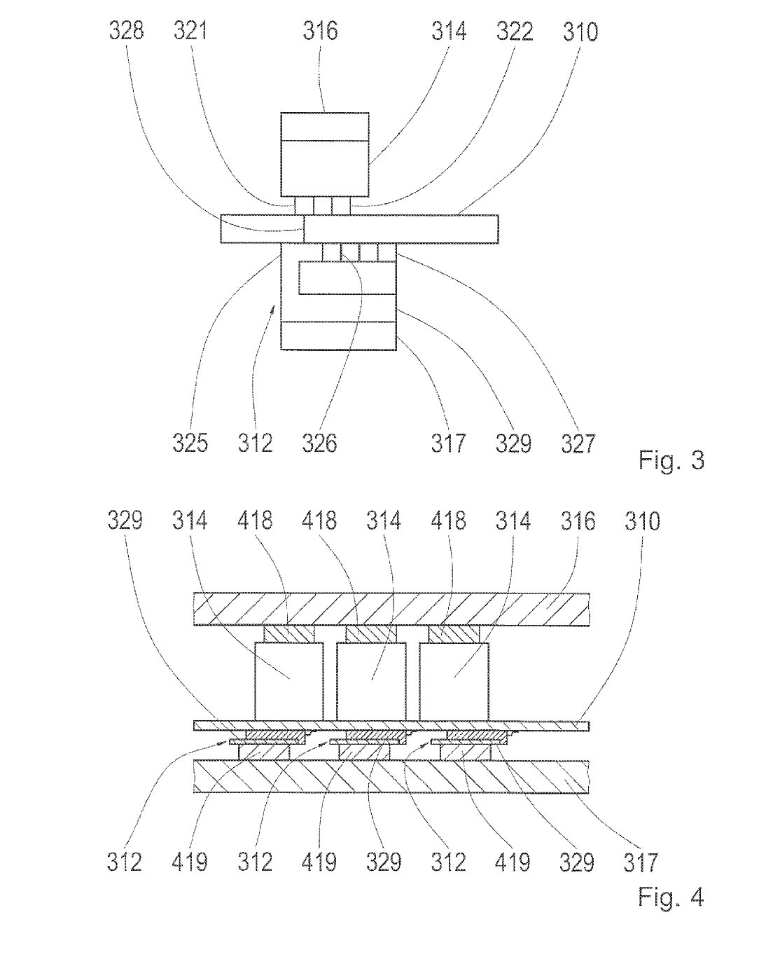

FIG. 3 shows an electrical circuit for controlling a load, according to an embodiment of the present embodiments;

FIG. 4 an electrical circuit for controlling a load, according to an embodiment of the present embodiments; and

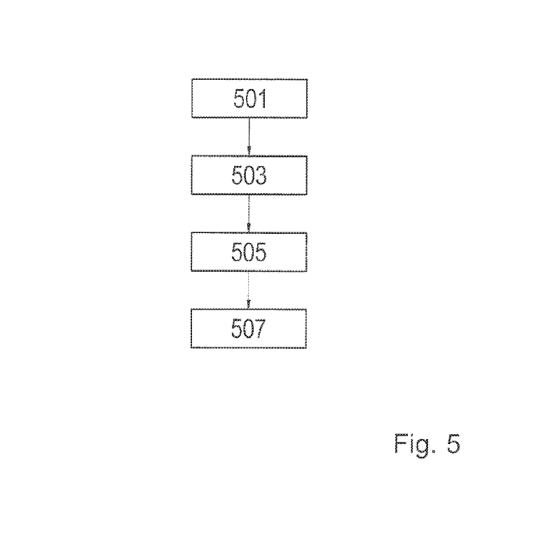

FIG. 5 a method of producing an electrical circuit for controlling a load, according to an embodiment of the present embodiments.

In the following description of preferred embodiments, same or similar reference numerals are used for the similarly acting elements shown in the various figures, a repeated description of these elements being dispensed with.

FIG. 1 shows a vehicle 100 with an electrical circuit 102 for controlling a load 104 according to an embodiment. The vehicle 100 can be for example a vehicle for the transport of persons, for example a motor vehicle or a rail vehicle. According to this embodiment, the load 104 is designed as an electric motor 104. This can be, for example, a drive motor 104 of the vehicle 100. Thus, the circuit 102 can represent drive electronics of an electric motor 104.

The electrical circuit 102 is formed to provide electrical energy to the motor 104 to operate it. For this purpose, the electrical circuit 102 comprises a suitable output interface, for example, in the form of a plug or in the form of electrical wiring. According to this embodiment, the electrical circuit 102 is connected two electrical leads to the motor 104. Thus, the motor 104 can be a DC motor. When the motor 104 is designed as a three-phase motor, the electrical circuit 102 can, for example, be connected to the motor 104 by three electrical leads.

The mechanical power provided by the motor 104 can be controlled by the electric power provided by the electrical circuit 102 to the motor 104. To provide the electrical power to the motor 104, the electrical circuit 102 comprises at least one power semiconductor, such as a power transistor. According to this embodiment, the electrical circuit 102 is connected with a power supply 106. The electrical circuit 102 is designed to receive the electrical power of the power supply 106, store it, for example, in an intermediate circuit capacitor and supply it in a controlled manner to the motor 104. The power supply 106 can be, for example, a battery of the vehicle 100.

Furthermore, the electrical circuit 102 according to this embodiment comprises an interface to a controller 108. The controller 108 is formed according to this embodiment to provide a control signal to the electrical circuit 102 for controlling the motor 104. For example, the control signal can be used to control the terminal of a power transistor of the electrical circuit 102, through which the electrical power is provided to the motor 104. In alternative embodiments, the power supply 106 and additionally or alternatively, the control device 108 can be included in the electrical circuit 102.

FIG. 2 shows an electrical circuit 202 for controlling a load. For example, the electrical circuit 202 can be used instead of the electrical circuit shown in FIG. 1 for controlling the load, for example the motor shown in FIG. 1.

The electrical circuit 202 comprises a circuit substrate 210. On a surface of the circuit substrate 210 are arranged three power end stages 212 and next to them three capacitors 214. The circuit substrate 210 is arranged in a housing, of which a housing upper side 216 and a bottom side 217 are shown. Between the circuit substrate 210 and the housing bottom 217 is a gap. Within the gap is arranged a thermally conductive material 219 opposite to each of the end stages 212, which allows a thermal coupling between the circuit substrate 210 and the housing bottom 117.

The capacitors 214 form an intermediate capacitor. For example, the three capacitors 214 can represent three parallel SMD electrolytic capacitors. The three power end stages 212 can be realized using standard MOSFETs.

FIG. 2 shows a possible design of an electrical circuit 202 for control of electric motors in the automotive sector. A special feature must be emphasized that the cooling of the power end stages 212 is done by the circuit substrate 210. The heat sink, such as the housing parts, which are also used for heat dissipation or heat sink, is located on the opposite side of the end stages 212. For EMC reasons, that is for the sake of electromagnetic compatibility, the intermediate circuit capacitor composed of the three capacitors 214 is formed as close as possible to the power end stages 212 placed and possibly also thermally attached to the heat sink.

FIG. 3 shows an electrical circuit 102 for controlling a load according to the present embodiments. For example, the electrical circuit 102 can represent the electrical circuit shown in FIG. 1.

The electrical circuit 102 has a circuit board 310. On a first surface of the circuit board 310 is arranged an intermediate circuit capacitor 314. On a second surface of the circuit board 310 opposite to the first surface is arranged a power semiconductor 312. According to this embodiment, the power semiconductor 312 is a power end stage for controlling an electric load and can be configured as a power transistor.

The intermediate circuit capacitor 314 is electrically conductively connected by two electrical terminals 321, 322 to electrical contact pads on the first surface of the circuit board 310.

The power semiconductor 312 is electrically conductively connected by three electrical terminals 325, 326,327 to electrical contact pads on the second surface of the circuit board 310.

The electrical terminals 321, 322, 325, 326, 327 can, for example, be designed as solder pads or solder tabs. For example, the intermediate circuit capacitor 314 and the power semiconductor 312 can be designed as SMD components.

According to an embodiment, a terminal 321 of the power semiconductor 312 is electrically conductively connected by through-connection 328 through the circuit board 310 with a connection 321 of the intermediate circuit capacitor 114.

The power semiconductor 312 has on one side, which in the mounted state is facing away from the circuit board 310, a heat conducting surface 329. The heat conducting surface 329 can, for example, be realized as a metal surface. The heat conducting surface 329 can fully cover the side of the power semiconductor 312 that is facing away from the circuit board 310. The power semiconductor 312 is designed as a so-called reverse component. One of the terminals 325, 326, 327 of the power semiconductor 312 is electrically conductively connected to the heat conducting surface 329. The terminal 325, 326, 327 electrically conductively connected to the heat conducting surface 329 can be a terminal different from a ground terminal. According to this embodiment, the power semiconductor 312 is designed as a MOSFET, and a drain terminal 325 the power semiconductor 312 is connected with the heat conducting surface 329.

To this end, an electrically conductive edge-joint, for example made of metal, can extend along an edge side of the power semiconductor 210. According to this embodiment, over the, the electrical terminal 325 of the power semiconductor 312 is connected with the heat conducting surface 329 by the edge-joint.

The heat conducting surface 329 can be used to dissipate the heat developing during the operation of the power semiconductor 312, for example, to a heat sink 317 attached to the heat conducting surface 329. The heat sink 317 can be designed as a separate component, for example, as a cooling plate. Alternatively, the heat sink 317 can be part of a housing that can completely or partially enclose the electrical circuit 102.

According to an embodiment, the capacitor 314 is also provided with a heat sink 316. The heat sink 316 can also be designed as a separate component or as part of the housing.

FIG. 4 shows an electric circuit 102 for controlling a load according the present embodiments. For example, the electrical circuit 102 can represent the electrical circuit shown in FIG. 1.

The electrical circuit 102 has a circuit board 310. On a first surface of the circuit board 310 are arranged three capacitors 314, which together form an intermediate circuit capacitor. On a second surface of the circuit substrate 310 opposite to the first surface are arranged three power semiconductors 312. According to this embodiment, the three power semiconductors 312 are each a power end stage for controlling an electric load. The power semiconductors 312 are each designed as a power transistor, or comprise at least one a power transistor. The number of capacitors 314 and power semiconductors 312 here is chosen merely exemplary and can be varied according to the requirements.

The three capacitors 314 are arranged adjacent to each other on the first surface of the circuit board 310. Similarly, the three power semiconductors 312 are arranged side by side on the second surface of the circuit board 310. Here, the power semiconductors 312 are arranged opposite to the capacitors 314. As shown in FIG. 4, in each case a power semiconductor 312 is arranged below a capacitor 314.

The power semiconductors 312 can be designed as described in FIG. 3. Of each of the power semiconductors 312 is shown a component body, which is connected by an electrical terminal 327 to the circuit board 310. On a side opposite to the mounting surface of the power semiconductor 312 is arranged a heat conducting surface 329.

According to an embodiment, each of the power semiconductors 312 represents a power end stage represents, which for example can be designed in the form of a reverse MOSET.

The intermediate circuit capacitor can be built of a plurality, here for example three, capacitors 314, which can be connected in parallel. The capacitors 314 can be designed as SMD electrolytic capacitors.

According to this embodiment, the electrical circuit 102 comprises a housing, of which in FIG. 4 are shown a top side 316 and a bottom case 317. The top side 316 and the bottom side 317 extend parallel to the circuit board 310. The circuit board 310 is provided between the top housing side 316 and the bottom housing side 317. The housing can have further parts so that the circuit board 310 can be partially or completely surrounded by the housing. For example, the housing top side 316 and the housing bottom side 317 can be connected with each other by side walls.

According to this embodiment, between the free ends of the capacitors 314, that is, between the sides of the capacitors 314 facing away from the circuit board 310 and a surface of the housing top side 316 facing the circuit board 310 is arranged a heat conductive material 418. In this case, an element made of thermally conductive material 418 can be arranged between a capacitor 314 and the top side of the housing 316. The heat-conducting material 418 can be used for cooling and mechanical support. For example, the housing top side 316 can be supported by the thermally conductive material 418 resting on the capacitors 314. In addition, waste heat from the capacitors 314 can be conducted by the thermally conductive material 418 to the housing top side 316 and out of the housing top side 316.

According to this embodiment, between the heat-conducting surfaces 329 of the power semiconductors 312 and a surface of the bottom side of the housing 317 facing the circuit board 310 is arranged another thermally conductive material 419. In this case, an element of thermally conductive material 419 can be arranged between a heat conducting surface 329 and the housing bottom side 317. The heat-conducting material 419 can be used for cooling and mechanical support. For example, the bottom side of the housing 317 can be supported by the thermally conductive material 419 resting on the power semiconductors 312. In addition, waste heat from the power semiconductor 312 can be conducted by the thermally conductive material 419 to the housing bottom side 317 and out of the bottom side 317.

The special design with simultaneous use of special components enables a very space-saving, thermally optimized and EMC-optimized arrangement. According to an embodiment, the so-called reverse end stages 312, for example, reverse-MOSFETs are used which are characterized in that the cooling connection, reverse-MOSFETs in the case of the drain terminal, lies on the opposite side of the soldered connection. Thus, the heat dissipation of the power end stages 312 occurs only slightly or not at all through the circuit board 310, but rather through the thermally conductive material 419, for example in the form of a sheet or paste directly to the heat sink, here a part of the housing of the electrical circuit 102. This allows equipping the other side of the circuit board 310 also with electrical components. If the intermediate circuit capacitor 314 is placed on the opposite side, an EMC-optimized connection is achieved. According to an embodiment, SMD electrolytic capacitors are used as capacitors 314, wherein several are connected in parallel. This result is a scalable solution which can be adjusted according to the load current which is provided to the load. Another special feature of this solution is the use of the so-called polymer electrolyte capacitors as capacitors 314. They have the advantage that due to the constant ESR (Equivalent Series Resistance) over temperature they are very well suitable for a parallel connection of the capacitors 314. Thus, a uniform distribution of the current load can be ensured. In addition, a thermal connection of SMD capacitors 314 by paste or film to the housing top side 316, which then serves as a heat sink, is provided. Furthermore, this connection by a thermally conductive material 314 serves as a mechanical support, which additionally protects the capacitors from vibration.

According to an embodiment, the reverse power output stages 312, specifically reverse-MOSFETs, are used, which are connected by the heat conductive material 419 to a lower housing part 317, which serves as a heat sink.

According to an embodiment, SMD electrolytic capacitors are used as capacitors 314, which ensure an optimized EMC connection, and are placed on the opposite side of the output stages 312 on the circuit substrate 310. In particular, several capacitors 314, preferably so-called polymer electrolytic capacitors, are connected in parallel. They are also connected by heat-conducting material 418 to the housing top side 316 for the purpose of cooling and/or vibration protection. They serve as a mechanical support and/or as a heat sink.

According to an embodiment, further electronic components, such as integrated circuits which are placed opposite to the power output stages, are arranged on the circuit board 310.

Direct FETs can also be used as output stages 312 instead of the reverse MOSFETs, wherein the soldering serves as additional tolerance. In the case of reverse MOSFETs, the drain connection (cooling surface) should not be tinned so as not to cause in the SMD soldering process melting of tin, which could worsen the tolerance heat sink.

FIG. 5 shows a flow diagram of a method for manufacturing an electrical circuit for controlling a load in accordance with the present embodiments. This can be a circuit described in the preceding figures.

In a step 501 is provided a circuit board. In steps 503, 505 at least one capacitor serving as an intermediate circuit capacitor is arranged on a surface of the circuit board and at least one power semiconductor is arranged on an opposite surface of the circuit board. The power semiconductor has a plurality of electrical terminals and a heat conducting surface on the side opposite to the contacting surface of the terminals, which is electrically connected to at least one of the electrical terminals, which are electrically conductively connected to at least one of the electrical terminals.

In a step 507, which can be performed separately or simultaneously with at least one of the steps 503, 505, the at least one intermediate capacitor and the at least one power semiconductor are electrically conductively connected to the circuit board and by at least one electric line of the circuit board also connected to each other.

The embodiments described and shown in the figures are chosen only as examples. Different embodiments can be combined completely or in respect of individual features. An embodiment can also be supplemented by the features of another embodiment. Furthermore, the process steps according to the present embodiments can be repeated and executed in a sequence other than the described one.

If an embodiment has a “and/or” link between a first feature and a second feature, it can be read so that the embodiment according to a variant may comprise both the first feature and the second feature, and according to another variant may comprise either only the first feature or only the second feature.

### REFERENCE NUMERALS

100 Vehicle
102 Electrical circuit
104 Load
106 Energy supply
108 Controller
202 Electrical circuit
210 Circuit board
212 End stages
214 Capacitors
216 Housing top side
217 Housing bottom side
219 Heat conduction material
310 Circuit board
312 Power semiconductor
314 Intermediate circuit capacitor
316 Housing top side
317 Housing bottom side
321 First terminal of the intermediate circuit capacitor
322 Second terminal of the intermediate circuit capacitor
325 First terminal of the power semiconductor
326 Second terminal of the power semiconductor
327 Third terminal of the power semiconductor
328 Through-contacting
329 Heat-conducting surface
418 Heat-conducting material
419 Thermally conductive material
501 Step of providing
503 Step of arranging an intermediate circuit capacitor
505 Step of arranging a power semiconductor
507 Step of connecting

1. An electrical circuit for controlling an electric motor for a vehicle, the electrical circuit comprising:
a circuit board having a first surface and a second surface opposite the first surface;
an intermediate circuit capacitor arranged on the first surface; and
a power semiconductor arranged on the second surface and electrically connected with the intermediate circuit capacitor for providing electrical energy to the electric motor,
wherein the intermediate circuit capacitor and the power semiconductor are arranged opposite to each other with respect to the circuit board.

2. The electrical circuit according to claim 1, wherein the power semiconductor comprises a reverse power end stage including a reverse MOSFET or a Direct FET.

3. The electric circuit according to claim 1, wherein the power semiconductor comprises at least a first electrical terminal and a second electrical terminal, wherein the first electrical terminal is connected to a heat conducting surface arranged on a side of the power semiconductor facing away from the second surface of the circuit board.

4. The electrical circuit according to claim 1, wherein the power semiconductor comprises at least a first electrical terminal and a second electrical terminal, wherein the first electrical terminal and the second electrical terminal are arranged on a side of the power semiconductor facing the second surface of the circuit board, and wherein the power semiconductor is configured to conduct the electric power for the electric motor through the first electrical terminal.

5. The electrical circuit according to claim 1, wherein the electrical circuit comprises a power semiconductor heat sink connected with a heat-conducting surface of the power semiconductor.

6. The electrical circuit according to claim 1, wherein the electrical circuit comprises an intermediate circuit capacitor heat sink connected with a side of the intermediate circuit capacitor facing away from the first surface of the circuit board.

7. The electrical circuit according to claim 5, wherein a thermally conductive material is arranged between the heat-conducting surface of the power semiconductor and the power semiconductor heat sink.

8. The electrical circuit according to claim 6, wherein the electrical circuit comprises a housing, wherein the circuit board is arranged within the housing, and wherein a first wall of the housing forms the intermediate circuit capacitor heat sink.

9. The electrical circuit according to claim 3, wherein the power semiconductor is configured as a transistor, wherein the first electrical terminal, the second electrical terminal, and a third electrical terminal of the transistor are electrically connected to the circuit board by at least one contacting surface arranged on the second surface of the circuit board.

10. The electrical circuit according to claim 1, wherein a base surface of the intermediate circuit capacitor facing the first surface of the circuit board overlaps a base surface of the power semiconductor facing the away from the second surface of the circuit board.

11. The electrical circuit according to claim 1, wherein the electrical circuit comprises a second intermediate circuit capacitor arranged on the first surface and a second power semiconductor arranged on the second surface and electrically connected to the second intermediate circuit capacitor for providing additional electrical power to the electric motor.

12. A method of manufacturing an electric circuit for controlling a load comprising:
arranging an intermediate circuit capacitor on a first surface of a circuit board, the circuit board having the first surface and a second surface opposite the first surface;
arranging a power semiconductor for providing electrical energy to the load on the second surface of the circuit board, wherein the power semiconductor comprises at least a first electrical terminal and a second electrical terminal, wherein the first electrical terminal is electrically connected to a heat-conducting surface arranged on a side of the power semiconductor facing away from the second surface of the circuit board; and
electrically connecting the power semiconductor with the intermediate circuit capacitor.

13. The method according to claim 12, wherein the power semiconductor comprises a reverse power end stage including a reverse MOSFET or a Direct FET.

14. The method according to claim 12, wherein the electrical circuit comprises a power semiconductor heat sink connected with the heat-conducting surface of the power semiconductor.

15. The method according to claim 12, wherein the electrical circuit comprises an intermediate circuit capacitor heat sink connected with a side of the intermediate circuit capacitor facing away from the first surface of the circuit board.

16. The method according to claim 12, wherein a thermally conductive material is arranged between the heat-conducting surface of the power semiconductor and the power semiconductor heat sink.

17. The method according to claim 12, wherein the power semiconductor is configured as a transistor, wherein the first electrical terminal, the second electrical terminal, and a third electrical terminal of the transistor are electrically connected to the circuit board by at least one contacting surface arranged on the second surface of the circuit board.

18. The electrical circuit according to claim 5, wherein a second side of the housing opposite to the first housing wall forms the power semiconductor heat sink.

19. The electrical circuit according to claim 6, wherein a thermally conductive material is arranged between the intermediate circuit capacitor heat sink and the first surface of the circuit board facing away from the intermediate circuit capacitor.

20. The electrical circuit according to claim 4, wherein the power semiconductor is configured as a transistor, wherein the first electrical terminal, the second electrical terminal, and a third electrical terminal of the transistor are electrically connected to the circuit board by contacting surfaces arranged on the second surface of the circuit board.
